(19) United States
(12) Patent Application Publication
(10) Pub. No.: US 2008/0245551 A1
(43) Pub. Date: Oct. 9, 2008

(54) CIRCUIT BOARD STRUCTURE FOR EMBEDDING SEMICONDUCTOR CHIP THEREIN AND METHOD FOR FABRICATING THE SAME

(75) Inventors: Pao-Hung Chou, Hsin-Chu (TW); Chi-Liang Chu, Hsin-Chu (TW); Wei-Chun Wang, Hsinchu (TW)

Correspondence Address: SCHMEISER OLSEN & WATTS, 18 E UNIVERSITY DRIVE, SUITE # 101, MESA, AZ, 85201, US

(73) Assignee: PHOENIX PRECISION TECHNOLOGY CORPORATION, Hsin-Chu (TW)

(21) Appl. No.: 12/099,299

(22) Filed: Apr. 8, 2008

(30) Foreign Application Priority Data
Apr. 9, 2007 (TW) 096112273

(51) Int. Cl. H05K 1/02; H05K 3/36

(52) U.S. Cl. 174/250; 29/830

(57) ABSTRACT

A semiconductor chip-embedded circuit board and a fabrication method thereof are provided, including: a core board having first and second surfaces with first and second circuit layers thereon respectively, the first surface having a chip-receiving area (CRA); a laminated layer formed on the first and second surfaces and formed with an opening for exposing the CRA; third and fourth circuit layers formed on the laminated layer, the third circuit layer having first and second conductive pads, the fourth circuit layer having third conductive pads; a first insulating protective layer formed on the third circuit layer and formed with a plurality of first openings for exposing the first conductive pads and the CRA and a plurality of second openings for exposing the second conductive pads; and a second insulating protective layer formed on the fourth circuit layer and formed with third openings for exposing the third conductive pads. Mounting a semiconductor chip on the CRA reduces package height.

### FIELD OF THE INVENTION

The present invention relates to a circuit board structure and a method for fabricating the same, and more particularly, to a circuit board structure for embedding a semiconductor chip therein and a method for fabricating the same.

### BACKGROUND OF THE INVENTION

Owing to the rapid growth of portable communication electronic devices, package structures such as BGA, flip chip, Chip-Size Package (CSP) and Multi-Chip Module (MCM) are becoming more popular, and even core boards for embedding semiconductor chips therein have been developed.

However, in a traditional semiconductor package structure, the semiconductor chip is attached to the top of a substrate and wire bonded or directly attached to the substrate surface by solder bumps (flip chip packaging), and then solder balls are attached to the back of the substrate for electrical connection. In so doing, although high pin counts can be achieved, the overall structural height is relatively great. Thus, semiconductor chips are embedded in the circuit boards for direct electrical connection with a view to reducing structural height and length of electrical conduction paths of semiconductor elements.

A conventional method for fabricating a semiconductor chip-embedded circuit board is illustrated with FIGS. 1A to 1C. A carrier board 1 comprises a first core board 11 and a second core board 12. The first core board 11 has a first surface 11a and a second surface 11b opposite to the first surface 11a. The second core board 12 has a first surface 12a and a second surface 12b opposite to the first surface 12a. At least an opening 120 penetrating the first surface 12a and the second surface 12b is formed in the second core board 12 (as shown in FIG. 1A). Thereafter, an adhesive layer 13 is used to bond the first core board 11 and the second core board 12 together, such that the first surface 11a of the first core board 11 is bonded to the second surface 12b of the second core board 12 through the adhesive layer 13 (as shown in FIG. 1B). Then, a semiconductor chip 14 is received in the opening 120 of the second core board 12. The semiconductor chip 14 has a first active face 14a and an inactive face 14b opposite to the first face 14a. The active face 14a has a plurality of electrode pads 141. The semiconductor chip 14 is mounted, via the inactive face 14b thereof, on the second surface 12b of the first core board 11 in the opening 120 of the second core board 12 (as shown in FIG. 1C).

Thereafter, build-up layers are formed on the first surface 12a of the second core board 12 and the active face 14a of the semiconductor chip 14, allowing the semiconductor chip 14 to have external electrical connection.

In the above conventional processes, the carrier board 1 for carrying the semiconductor chip 14 comprises the first and second core boards 11 and 12 bonded together, thus package height cannot be reduced.

Additionally, since the carrier board 1 comprises the first and second core boards 11 and 12, two core boards with different structures have to be prepared in the pre-process. Moreover, build-up layers have to be formed on the first surface 12a of the second core board 12 and the active face 14a of the semiconductor chip 14 in order to provide external electrical connection for the semiconductor chip 14, the structural complexity is increased, so are the fabrication processes.

Thus, there is a need for a circuit board structure embedded with a semiconductor chip that minimizes package height and complexity of the fabrication processes.

### SUMMARY OF THE INVENTION

In the light of foregoing drawbacks of the prior art, an objective of the present invention is to provide a circuit board structure for embedding a semiconductor chip therein and a method for fabricating the same to reduce overall semiconductor package height.

Another objective of the present invention is to provide a circuit board structure for embedding a semiconductor chip therein and a method for fabricating the same to simplify the process.

In accordance with the above and other objectives, the present invention provides a circuit board structure for embedding a semiconductor chip therein, which may include: a core board having a first surface and a second surface, the first surface and the second surface having a first circuit layer and a second circuit layer formed thereon respectively, and the first surface having a chip receiving area; a laminated layer formed on the first and second surfaces of the core board and the first and second circuit layers having at least one opening for exposing the chip receiving area; third and fourth circuit layers formed on the laminated layer of the first and second surfaces respectively, the third circuit layer having a plurality of first and second conductive pads, the fourth circuit layer having a plurality of third conductive pads; a first insulating protective layer formed on the laminated layer and the third circuit layer and formed with a plurality of first openings for exposing the first conductive pads in the third circuit layer and the chip receiving area and a plurality of second openings for exposing the second conductive pads in the third circuit layer; and a second insulating protective layer formed on the laminated layer and the fourth circuit layer and formed with a plurality of third openings for exposing the third conductive pads in the fourth circuit layer.

The core board can be an insulating board or a circuit board with built-in circuit layers. The third and fourth circuit layers can be patterned from a metal layer, a conductive layer, and a thin metal layer.

A metal protective layer can be formed on the first conductive pads. A semiconductor chip is received in the opening of the laminated layer. The semiconductor chip has active and inactive faces. The active face has a plurality of electrode pads. The semiconductor chip is mounted on the chip receiving area in the opening via the inactive face. First conductive elements (such as metal wires) are formed to electrically connect the metal protective layer on the first conductive pads to the electrode pads of the semiconductor chip, so that the semiconductor chip is electrically connected to the third circuit layer. A metal protective layer can be formed on the second and third conductive pads. A plurality of second conductive elements (such as solder balls) can be formed on the metal protective layer on the second and third conductive pads.

The present invention further provides a method for fabricating a circuit board for embedding a semiconductor chip therein, which may comprise: providing a core board having a first surface and a second surface, the first surface and the second surface having a first circuit layer and a second circuit layer formed thereon respectively, and the first surface having a chip receiving area with a metal pad formed thereon; forming a laminated layer on the first and second surfaces of the core board and the first and second circuit layers respectively; forming an opening in the laminated layer on the first surface to expose the metal pad; forming third and fourth circuit layers on the laminated layer on the first and second surfaces respectively, the third circuit layer having a plurality of first and second conductive pads, the fourth circuit layer having a plurality of third conductive pads, removing the metal pad to expose the chip receiving area; forming a first insulating protective layer on the laminated layer and the third circuit layer and forming a first opening in the first insulating protective layer to expose the first conductive pads in the third circuit layer and the chip receiving area and a plurality of second openings for exposing the second conductive pads in the third circuit layer; and forming a second insulating protective layer on the laminated layer and the fourth circuit layer and forming a plurality of third openings in the second insulating protective layer to expose the third conductive pads in the fourth circuit layer.

A thin metal layer can be laminated onto the outer surface of the laminated layer, which is a resin clad copper foil (RCC), for example. The steps of forming the third and fourth circuit layers on the laminated layer may include: forming a conductive layer on a thin metal layer of the laminated layer, the sidewalls of the openings, and the metal pad; forming a metal layer on the conductive layer; patterning the metal layer, the conductive layer and the thin metal layer to form the third and fourth circuit layers.

The core board can be an insulating board or a circuit board with built-in circuit layers. A metal protective layer can be formed on the first conductive pads. A semiconductor chip is received in the opening of the laminated layer. The semiconductor chip has active and inactive faces. The active face has a plurality of electrode pads. The semiconductor chip is mounted in the chip receiving area in the opening via the inactive face. First conductive elements (e.g. metal wires) can be formed for electrically connecting the metal protective layer on the first conductive pads and the electrode pads of the semiconductor chip.

The fourth circuit layer may further include a plurality of third conductive pads. A second insulating protective layer can be formed on the laminated layer and the fourth circuit layer. Third openings can be formed in the second insulating protective layer to expose the third conductive pads in the fourth circuit layer. A metal protective layer can be further formed on the third conductive pads. A plurality of second conductive elements (e.g. solder balls) can be formed on the metal protective layer on the second and third conductive pads.

The circuit board structure for embedding a semiconductor chip therein and the method for fabricating the same of the present invention essentially allows a laminated layer to be formed on the first surface and the second surface of the core board respectively. The laminated layer on the first surface of the core board has an opening for receiving a semiconductor chip, so that the semiconductor chip is embedded in the laminated layer. Since only one core board, instead of two core boards, is used, structural height and process complexity can be reduced. Moreover, the opening in the laminated layer exposes the first conductive pads of the third circuit layer, such that the first conductive elements, such as metal wires, can electrically connects the semiconductor chip and the first conductive pads.

### BRIEF DESCRIPTION OF THE DRAWINGS

The present invention can be more fully understood by reading the following detailed description of the preferred embodiments, with reference made to the accompanying drawings, wherein:

FIGS. 1A to 1C are cross-sectional views illustrating a convention method for fabricating a semiconductor chip-embedded circuit board structure; and

FIGS. 2A to 2I are cross-sectional views illustrating a circuit board structure for embedding a semiconductor chip therein and a method for fabricating the same according to a preferred embodiment of the present invention.

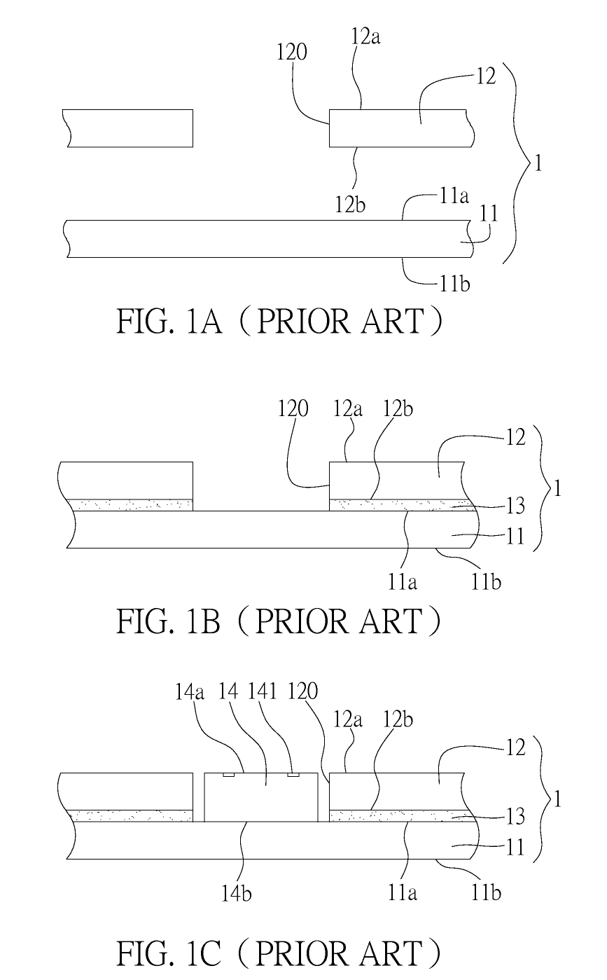

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

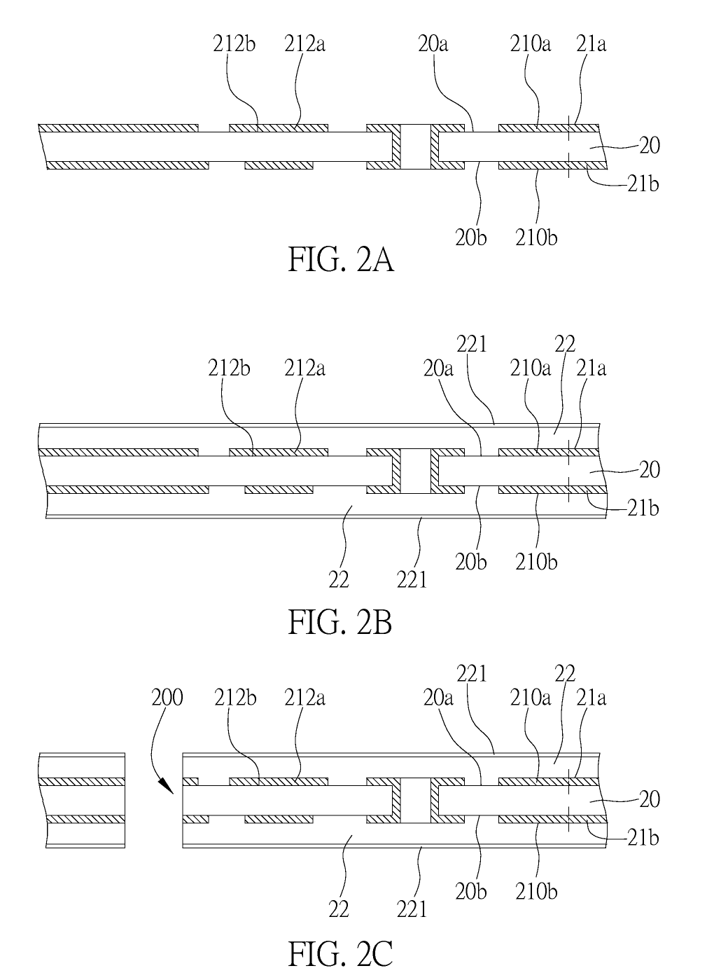

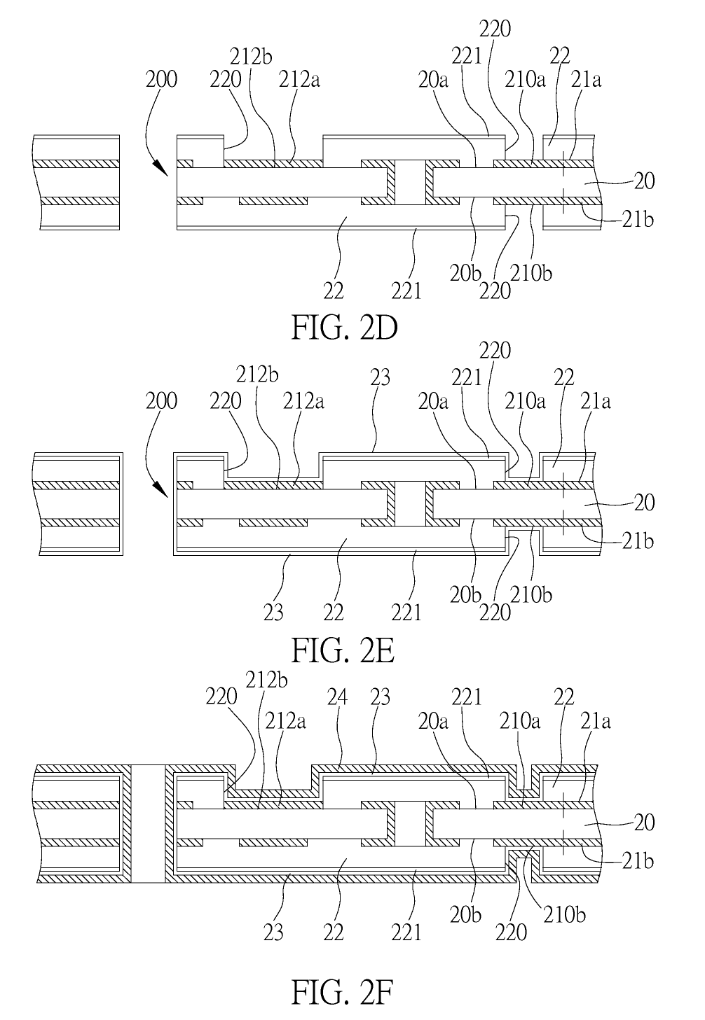

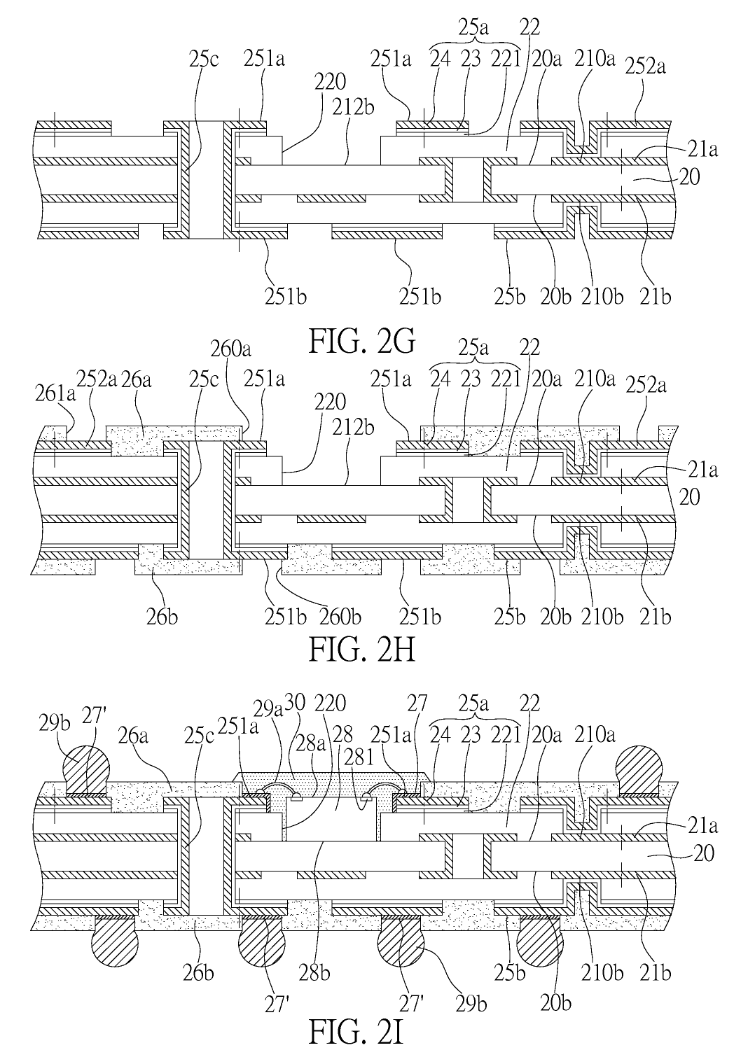

FIGS. 2A to 2I are cross-sectional views illustrating a method for fabricating a circuit board structure for embedding a semiconductor chip therein according to a preferred embodiment of the present invention.

Referring to FIG. 2A, a core board 20 with a first surface 20a and a second surface 20b is provided. The first surface 20a and the second surface 20b have a first circuit layer 21a and a second circuit layer 21b respectively. The first circuit layer 21a has a plurality of conductive lands 210a and at least one metal pad 212a. Underlying the metal pad 212a is a chip receiving area 212b. The second circuit layer 21b has a plurality of conductive lands 210b. The core board 20 is an insulating board or a circuit board with circuit layers.

Referring to FIG. 2B, a laminated layer 22 is formed on the first and second surfaces 20a and 20b of the core board 20 and the first and second circuit layers 21a and 21b respectively. A thin metal layer 221, such as a resin clad copper foil (RCC), is laminated onto the outer surface of the laminated layer 22.

Referring to FIG. 2C, at least one penetrating through hole 200 is mechanically drilled or laser-drilled in the laminated layer 22 laminated with the thin metal layer 221 and the core board 20 having the first and second circuit layers 21a and 21b.

Referring to FIG. 2D, a plurality of openings 220 are laser-drilled in the laminated layer 22 having the thin metal layer 221 to expose the conductive lands 210a and the metal pad 212a in the first circuit layer 21a and the conductive lands 210b in the second circuit layer 21b, wherein the conductive lands 210a and the metal pad 212a may function as laser blocking layers.

Referring to FIG. 2E, a conductive layer 23 is formed on the surfaces of the thin metal layer 221, the conductive lands 210a and 210b, the metal pad 212a, the through hole 200, and the openings 220 of the laminated layer. The conductive layer 23 essentially act as an electrical conduction path required for subsequently electroplating metal materials and can be made of a metal or a plurality of deposited metal layers. It can be selected from a mono-layer or multi-layer structure made of copper, tin, nickel, chromium, titanium, copper-chromium and the like.

Referring to FIG. 2F, a metal layer 24 is formed on the conductive layer 23. The metal layer 24 can be made of one selected from lead, tin, silver, copper, gold, bismuth, antimony, zinc, nickel, zirconium, magnesium, indium, tellurium and gallium. In practice, copper is a relatively cheap and mature electroplating material. However, the present invention is not limited to this.

Referring to FIG. 2G, a third circuit layer 25a and a fourth circuit layer 25b are patterned onto the metal layer 24, the conductive layer 23 and the thin metal layer 221 above the laminated layer 22 on the first surface 20a and the second surface 20b of the core board 20 respectively. A plated through hole (PTH) 25c is formed in the through hole 200 to electrically connect the third circuit layer 25a and the fourth circuit layer 25b. The third circuit layer 25a further includes a plurality of first conductive pads 251a and second conductive pads 252a. The fourth circuit layer 25b further includes a plurality of third conductive pads 251b. Then, the metal layer 24, the conductive layer 23, the thin metal layer 221 and the metal pad 212a in the opening 220 of the laminated layer are removed to expose the chip receiving area 212b. The processes for forming the third and fourth circuit layers 25a and 25b abound and are well known in the art, thus they will not be further described in order not to obscure the technical features of the present invention.

Referring to FIG. 2H, a first insulating protective layer 26a is formed on the laminated layer 22 on the first surface 20a of the core board 20 and the third circuit layer 25a. In the first insulating protective layer 26a, a plurality of first openings 260a are formed to expose the first conductive pads 251a in the third circuit layer 25a and the chip receiving area 212b in the opening 220 and a plurality of second openings 261a are formed for exposing the second conductive pads 252a in the third circuit layer 25a. Referring to FIG. 2H again, a second insulating protective layer 26b is formed on the laminated layer 22 on the second surface 20b of the core board 20 and the fourth circuit layer 25b, with a plurality of third openings 260b formed in the second insulating protective layer 26b to expose the third conductive pads 251b in the fourth circuit layer 25b.

The first and second insulating protective layers 26a and 26b are organic or inorganic anti-oxidation film that can be made of any kind of dewetting solder resist materials.

Referring to FIG. 2I, a metal protective layer 27 is formed on the first conductive pads 251a by physical or chemical deposition. Typically, the metal protective layer 27 is made of nickel/gold. A semiconductor chip 28 is received in the opening 220. The semiconductor chip 28 has an active face 28a and an opposing inactive face 28b. The active face 28a has a plurality of electrode pads 281. The semiconductor chip 28 is mounted in the chip receiving area 212b in the opening 220 via the inactive face 28b. First conductive elements 29a (metal wires) are formed between the metal protective layer 27 on the first conductive pads 251a and the electrode pads 281 of the semiconductor chip 28, thereby electrically connecting the semiconductor chip 28 to the first conductive pads 251a of the third circuit layer 25a. An encapsulant 30 for encapsulating the first conductive pads 251a, the first conductive elements 29a and the semiconductor chip 28 is further formed thereon.

Another metal protective layer 27′ is formed on the second and third conductive pads 252a and 251b. Second conductive elements 29b (such as solder balls) are formed on the metal protective layer 27′ for providing electrical connection with an external device (not shown). Thus, a package structure is formed, and the second conductive elements 29b are allowed to electrically connect the third conductive pads 251b stacked on another package structure to the second conductive pads 252a, thus forming a package on package structure.

The metal protective layers 27 and 27′ can be made of a material selected from copper, tin, lead, silver, nickel, gold, platinum, phosphorous or alloys thereof or an organic solderability preservative.

The present invention further provides a circuit board structure for embedding a semiconductor chip therein in accordance with the above method, which comprises: a core board 20 having a first surface 20a and a second surface 20b, the first surface 20a being formed with a first circuit layer 21a thereon and a chip receiving area 212b, and the second surface 20b being formed with a second circuit layer 21b thereon respectively; laminated layers 22 formed on the first surface 20a and the first circuit layer 21a on the first surface 20a as well as the second surface 20b and the second circuit layer 21b on the second surface 20b, wherein an opening 220 is formed in the laminated layers 22 on the first surface 20a to expose the chip receiving area 212b; third and fourth circuit layers 25a and 25b formed on the laminated layers 22 on the first and second surfaces 20a and 20b respectively, the third circuit layer 25a having a plurality of first and second conductive pads 251a and 252a, the fourth circuit layer 25b having a plurality of third conductive pads 251b, wherein the third and fourth circuit layers 25a and 25b are patterned from a metal layer 24, a conductive layer 23 or a thin metal layer 221; a first insulating protective layer 26a formed on the laminated layers 22 and the third circuit layer 25a, wherein in the first insulating protective layer 26a, a plurality of first openings 260 are formed for exposing the first conductive pads 251a in the third circuit layer 25a and the opening 220 of the laminated layers 22 and a plurality of second openings 261a are formed for exposing the second conductive pads 252a in the third circuit layer 25a; and a second insulating protective layer 26a formed on the laminated layers 22 and the fourth circuit layer 25b, wherein a plurality of third openings 260b are formed in the second insulating protective layer 26a to expose the third conductive pads 251b in the fourth circuit layer 25b.

A metal protective layer 27 is formed on the first conductive pads 251a. A semiconductor chip 28 is received in the opening 220 of the laminated layer 22. The semiconductor chip 28 has an active face 28a and an inactive face 28b. The active face 28a has a plurality of electrode pads 281. The semiconductor chip 28 is mounted in the chip receiving area 212b in the opening 220 via the inactive face 28b. First conductive elements 29a (metal wires) electrically connect the electrode pads 281 of the semiconductor chip 28 and the metal protective layer 27 on the first conductive pads 251a, such that the semiconductor chip 28 is electrically connected to the third circuit layer 25a via the first conductive elements 29a.

Another metal protective layer 27′ is formed on the second and third conductive pads 252a and 251b. Second conductive elements 29b (such as solder balls) are formed on the metal protective layer 27′ for external electrical connection with other electronic devices.

The circuit board structure for embedding a semiconductor chip therein and the method for fabricating the same essentially allow the laminated layer to be formed on the first surface and the second surface of the core board respectively. The laminated layer on the first surface of the core board has an opening for receiving a semiconductor chip, so that the semiconductor chip is mounted on the chip receiving area and thereby embedded in the laminated layer. Since only one core board, instead of two core boards, is used, structural height and process complexity can be reduced. Moreover, the first conductive pads of the third circuit layer are exposed from the opening in the laminated layer, such that the first conductive elements such as metal wires can electrically connects the semiconductor chip and the first conductive pads.

The above embodiments only illustrate the principles of the present invention, and they should not be construed as to limit the present invention in any way. The above embodiments can be modified by those with ordinary skills in the art without departing from the scope of the present invention as defined in the following appended claims.

What is claimed is:

1. A circuit board structure for embedding a semiconductor chip therein, comprising:
a core board having a first surface and a second surface, the first surface having a first circuit layer thereon and formed with a chip receiving area, and the second surface having a second circuit layer thereon;
laminated layers formed on the first surface and the first circuit layer formed on the first surface and the second surface and the second circuit layer formed on the second surface, respectively, wherein at least an opening for exposing the chip receiving area is formed in the laminated layer;
third and fourth circuit layers formed on the laminated layers on the first and second surfaces of the core board respectively, the third circuit layer having a plurality of first and second conductive pads, and the fourth circuit layer having a plurality of third conductive pads;
a first insulating protective layer formed on the third circuit layer and the laminated layer formed on the third circuit layer, wherein a first opening is formed in the first insulating protective layer to expose the first conductive pads in the third circuit layer and the chip receiving area and a plurality of second openings are formed in the first insulating protective layer to expose the second conductive pads in the third circuit layer; and
a second insulating protective layer formed on the fourth circuit layer and the laminated layer formed on the fourth circuit layer, wherein a plurality of third openings are formed in the second insulating protective layer to expose the third conductive pads in the fourth circuit layer.

2. The circuit board structure of claim 1, wherein the core board is one of an insulating board and a circuit board with built-in circuit layers.

3. The circuit board structure of claim 1, wherein the third and fourth circuit layers are each patterned from a metal layer, a conductive layer, or a thin metal layer.

4. The circuit board structure of claim 1, further comprising a metal protective layer formed on the first conductive pads.

5. The circuit board structure of claim 4, further comprising a semiconductor chip received in the opening of the laminated layer, the semiconductor chip having an active face formed with a plurality of electrode pads and an opposing inactive face, wherein the semiconductor chip is mounted on the chip receiving area in the opening via the inactive face thereof.

6. The circuit board structure of claim 5, further comprising a plurality of first conductive elements for electrically connecting the metal protective layer on the first conductive pads and the electrode pads of the semiconductor chip.

7. The circuit board structure of claim 6, wherein the first conductive elements are metal wires.

8. The circuit board structure of claim 1, further comprising a metal protective layer formed on the second and third conductive pads.

9. The circuit board structure of claim 8, further comprising a plurality of second conductive elements formed on the metal protective layer on the second and third conductive pads.

10. A method for fabricating a circuit board for embedding a semiconductor chip therein, comprising:
providing a core board having a first surface and a second surface, the first surface having a first circuit layer thereon and formed with a chip receiving area, and the second surface having a second circuit layer thereon, wherein on the chip receiving area a metal pad is formed;
forming laminated layers on the first surface and the first circuit layer on the first surface and the second surface and the second circuit layer on the second surface, respectively;
forming an opening in the laminated layer on the first surface to expose the metal pad;
forming third and fourth circuit layers on the laminated layers on the first and second surfaces respectively, the third circuit layer having a plurality of first and second conductive pads, the fourth circuit layer having a plurality of third conductive pads, and removing via the opening the metal pad to expose the chip receiving area; and
forming a first insulating protective layer on the laminated layer and the third circuit layer, a plurality of first openings formed in the first insulating protective layer for exposing the first conductive pads in the third circuit layer and the chip receiving area and a plurality of second openings formed for exposing the second conductive pads in the third circuit layer; and forming a second insulating protective layer on the laminated layer and the fourth circuit layer, with a plurality of third openings formed in the second insulating protective layer to expose the third conductive pads in the fourth circuit layer.

11. The method of claim 10, wherein the core board is one of an insulating board and a circuit board with built-in circuit layers.

12. The method of claim 10, wherein a thin metal layer is laminated onto an outer surface of the laminated layer.

13. The method of claim 10, wherein the laminated layer is a resin clad copper foil (RCC).

14. The method of claim 10, wherein each of the steps of forming the third and fourth circuit layers on the laminated layer include:
forming a conductive layer on a thin metal layer or the laminated layer, sidewalls of the openings, and the metal pad;
forming a metal layer on the conductive layer; and
patterning the metal layer, the conductive layer, and the thin metal layer to form the third and fourth circuit layers.

15. The method of claim 14, further comprising forming a metal protective layer on the first conductive pads.

16. The method of claim 10, further comprising receiving a semiconductor chip in the opening of the laminated layer, the semiconductor chip having an active face with a plurality of electrode pads formed thereon and an opposing inactive face, wherein the semiconductor chip is mounted on the chip receiving area in the opening via the inactive face.

17. The method of claim 16, further comprising forming a plurality of first conductive elements for electrically connecting the metal protective layer on the first conductive pads and the electrode pads of the semiconductor chip.

18. The method of claim 17, wherein the first conductive elements are metal wires.

19. The method of claim 10, further comprising forming a metal protective layer on the second and third conductive pads.

20. The method of claim 19, further comprising forming a plurality of second conductive elements on the metal protective layer on the second and third conductive pads.
